(19) United States
(12) Patent Application Publication
(10) Pub. No.: US 2010/0214230 A1
(43) Pub. Date: Aug. 26, 2010

(54) ITO layer manufacturing process & application structure

(76) Inventors: Jau-Jier Chu, Hsin-Chu (TW); I-Wen Lee, Hsin-Chu (TW); Shih-Liang Chou, Hsin-Chu (TW); Po-Yao Lai, Hsin-Chu (TW); Chien-Min Weng, Hsin-Chu (TW)

Correspondence Address: Jackson Intellectual Property Group PLLC, 106 Starvale Lane, Shipman, VA, 22971, US

(21) Appl. No.: 11/978,555

(22) Filed: Oct. 30, 2007

(51) Int. Cl. G06F 3/041; B32B 17/06; B32B 27/06; C23C 14/34

(52) U.S. Cl. 345/173; 428/336; 204/192.15; 204/192.14

(57) ABSTRACT

A two-stage manufacturing process for preparation of an ITO layer includes having first a transparent substrate, e.g., a glass or plastic substrate going through treatment without preheating; the substrate is then sputtering processed in a sputtering chamber under process conditions without heating up to form a amorphous state ITO film on the surface of the transparent substrate; followed with a thermal treatment at a preset temperature to turn the ITO layer into a crystalline state without compromising strength of the glass or the plastic substrate while delivering a durable ITO layer and a structure of ITO layer provided with a specific sheet resistance and/or thickness. The ITO layer produced using the present invention particularly fits to be applied in a touch screen structure.

### BACKGROUND OF THE INVENTION

(a) Field of the Invention

The present invention is related to an ITO layer manufacturing process, known as a two-stage film process by crystallization, and more particularly, to an ITO layer provided with specific sheet resistance and/or thickness ITO layer structure best appropriately to be applied in a touch screen structure that delivers better environment durability property and better sheet resistance uniformity, lower sheet resistance variation, better scratch proof, and longer service life.

(b) Description of the Prior Art

Indium Tin Oxide (ITO) transparent conductive film is one of star products having research efforts and economic values and it is generally applied in car-laden LCD, touch panel, EMI RF shielding glass, liquid crystal wrist watch, liquid crystal panel on electric home appliance, solar cell, portable liquid crystal TV game unit, PDP, EL, LCD, and electrode for color filter.

The ITO is made by having indium oxide doped with small amount of tin oxide to have tin atoms to replace certain indium atoms existing in the structure of indium oxide. Therefore, in terms of the composition of its general structure, Indium oxide (In₂O₃) dominates. Indium oxide related to an oxide of semiconductor material not only presents a high band gap (Eg≧2.9 eV) for light to permeate but also contains high concentration of carriers and mobility. Of course, depending on the individual conductivity, the applied range of indium oxide varies. Conductive characteristic of the ITO layer essentially comes from two types of charge carriers, respectively tin doping and oxygen vacancy. That is, by having tin doping controlled at a constant amount, conductive characteristic varies depending on the charge carrier of oxygen vacancy. When the location of the lattice oxygen is not filled in oxygen vacancy in the ITO layer, two electrons otherwise bonded are then released to become free electrons; therefore, oxygen vacancy increases conductivity of ITO in taking a form of n-type donor. Concentration of oxygen vacancy will be affected by conditions of a sputtering process, e.g. vacuum and temperature; and the concentration of oxygen vacancy will also affect the charge and sheet resistance of the ITO layer as a whole.

Whereas demand of ITO transparent conductive film is increasing in the market, positively searching for a good and economic preparation process for ITO layer has been put on the top priority. As illustrated in FIG. 1, an ITO layer manufacturing process of the prior art is referred as a single stage thin film process by crystallization. Wherein, a transparent material, e.g., a glass substrate, is heated at 200˜400° C. for 10 up to 30 minutes before being put in a sputtering chamber for ITO sputtering process at the same high temperature range; the glass substrate having completed the sputtering process is fast cooled down to form a crystalline ITO layer on the glass substrate.

However, the crystalline ITO layer resulted from using high temperature sputtering in the prior art features high concentration of oxygen vacancy and good conductivity, but the film can best reach approximately 5-20 nm and is not thick enough when a specific sheet resistance (e.g. 500Ω/square) must be achieved; and its surface roughness, Ra, usually stays only in a range of 0.2˜0.5 nm and that is not rough enough. As a result, the ITO layer is not scratch resisting, friction resisting, and durable; meanwhile, rate of variation of its sheet resistance is comparatively greater for being subject to high temperature and high humidity environment. The consistence of the entire ITO layer is poor to create dispersion when applied in a touch screen to fail precise calculation of touch coordinates.

The single stage film process used by the prior art usually is applicable to formation of an ITO layer with lower sheet resistance, e.g., approximately a range of 20˜80052/square, and 200Ω/square inter alia. However, difficulties confront the manufacturing process of the prior art in the manufacturing an ITO layer with higher sheet resistance.

Furthermore, in the prior art, strength of the glass substrate is weakened since the glass substrate must be rapidly heated up at high temperature and completed with the sputtering process before cooling down rapidly while the sputtering temperature is too high for the plastic base material to handle. Therefore, application scope of the prior art is significantly compromised due to that it is not applicable to plastic base material

### SUMMARY OF THE INVENTION

The primary purpose of the present invention is to provide an ITO layer manufacturing process that yields better environment durability property and better sheet resistance uniformity, scratch proof, and longer service life that is particularly applicable to the manufacturing of an ITO layer for touch screen.

To achieve the purpose, a substrate is prepared before going through ITO sputtering process in the sputtering chamber without heating (or at a temperature below the range of 200˜400° C. applied in the prior art) to form an ITO layer in amorphous state and finally the substrate is thermally treated for the ITO layer to turn into crystalline, known as a two-stage crystalline film process.

One efficacy of the present invention is that the substrate maintains its original strength since in the process the substrate is not experiencing the cycle of heating up and staying at high temperature for sputtering and then drastically cooled down.

Another efficacy of the present invention is that the ITO layer developed in the sputtering chamber is in its amorphous state under the process conditions without being heated up before the thermal treatment to turn into crystalline status; therefore, concentration of oxygen vacancy is lower than that made from the single stage crystalline film process of the prior art, thus is less vulnerable to heat and wet, i.e., better environment durability property; delivers better uniformity of the entire ITO layer, i.e., ITO layer uniformity having been improved, and lower variation rate of sheet resistance.

Another efficacy yet of the present invention is that the resultant ITO layer crystalline is complete and refine, containing comparatively larger grains, rougher surface of the ITO layer; and thus better friction resistant to better withstand scratch and provide longer service life.

### BRIEF DESCRIPTION OF THE DRAWINGS

FIG. 1 shows a process flow path for manufacturing ITO transparent conductive layer of a single stage crystalline film process of the prior art.

FIG. 2 shows a manufacturing process of the present invention.

FIG. 3 is a chart showing variation of sheet resistance under different temperatures of ITO glass finished products respectively from using the single stage crystalline film process of prior art and a two-stage crystalline film process of the present invention.

FIG. 4 is a chart showing variations of sheet resistance uniformity under different temperatures of ITO glass finished products respectively from using the single stage crystalline film process of prior art and the two-stage crystalline film process of the present invention.

FIG. 5 is a chart showing variations of sheet resistance under 60° C., 90% RH, and 500 hours of ITO glass finished products respectively from using the single stage crystalline film process of prior art and the two stage crystalline film process of the present invention.

FIG. 6 is a chart showing variations of sheet resistance uniformity under 60° C., 90% RH, and 500 hours of ITO glass finished products respectively from using the single stage crystalline film process of prior art and the two stage crystalline film process of the present invention.

FIG. 7 is an X-ray diffraction pattern showing analysis of crystalline extents of ITO glass finished products respectively from using the single stage crystalline film process of prior art and the two-stage crystalline film process of the present invention.

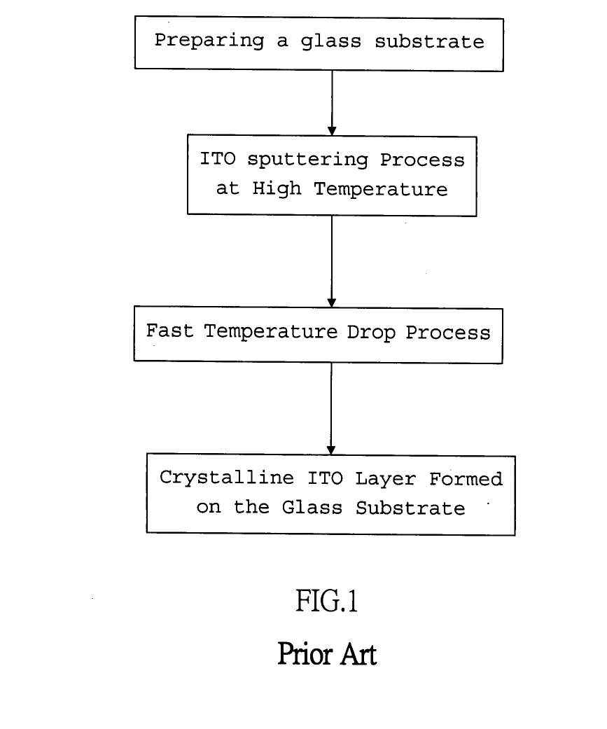

### DETAILED DESCRIPTION OF THE PREFERRED EMBODIMENTS

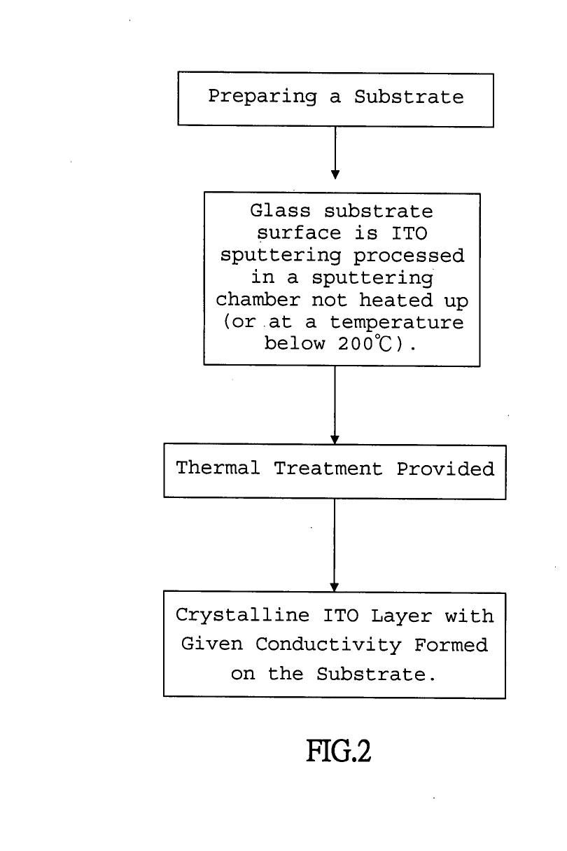

The present invention essentially disclosing an ITO layer manufacturing process that delivers the ITO layer with better environment durability property and better sheet resistance uniformity, lower variation rate of sheet resistance, more scratch resistant and longer service life, is comprised of the following steps as also illustrated in FIG. 2:

a. Preparing a substrate: the substrate may be related to a transparent glass or plastic substrate; if a glass substrate is selected, a Soda Lim Glass or a Quartz Glass is preferred; and if a plastic substrate is selected, a Polycarbonate (PC), polymethyl methacrylate (PMMA), or Polyethylene terephthalate (PET) is preferred, and PC inter alia. The cut glass substrate is cleaned first with detergent to rid of oil stains and dusts found on the surface and the glass substrate, and then the glass substrate is rinsed with deionized water (DI water) to eliminate residual detergent and impurities found on the surface of the glass substrate. The clean glass substrate is blown to dry using clean dry air (CDA) to rule out any residual water stain on the glass substrate while clearing off any dust attached to the surface of the glass substrate. The glass substrate is dried using a hot air knife and then properly stored for use.

b. An ITO layer process is provided on the surface of the substrate. A sputtering chamber is not heated or heated up to a temperature below the range 200° C.˜400° C. of the prior art to form the ITO layer on the surface of the substrate by means of a sputter to from a semi-finished product when the ITO layer is in its amorphous state. Wherein, the substrate may not be preheated before going through ITO layer sputtering process.

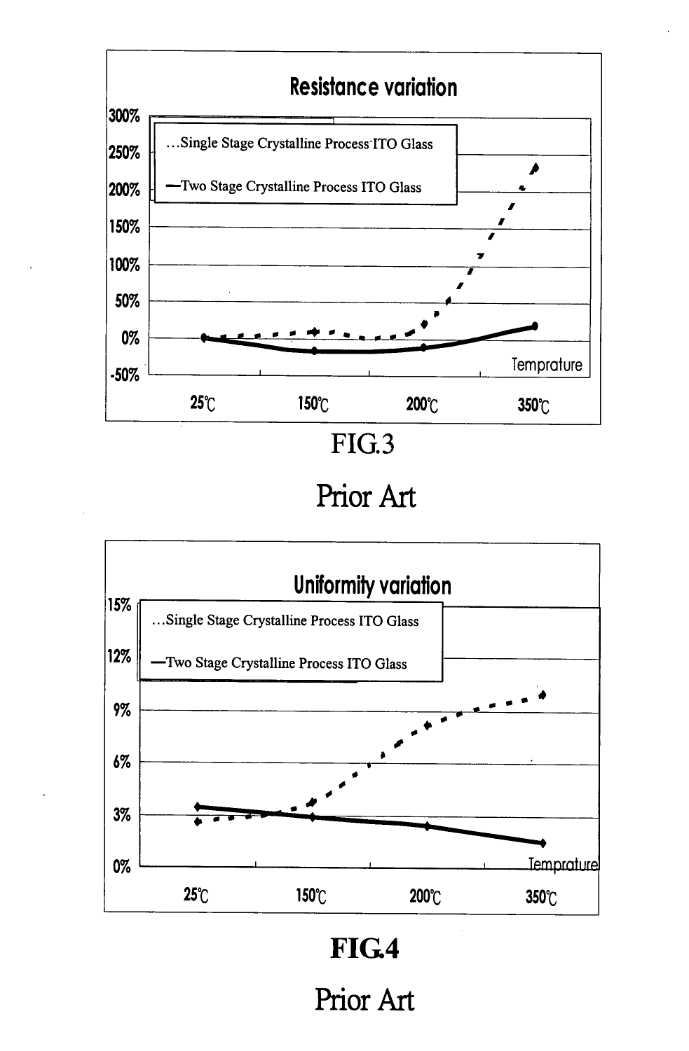

c. Thermal Treatment. The semi-finished product is then placed in or passes through a heating device (e.g., an oven) to be treated at a preset temperature depending on the nature of the individual substrate to form the ITO layer in different crystalline formation: (1) a crystalline ITO layer is formed on the glass substrate in thermal treatment for 30 minutes up to 3 hours at a temperature range of 150˜400° C., and 300˜400° C. is preferred; or (2) another crystalline state of ITO layer is formed on the plastic substrate in a thermal treatment provided at a temperature below 200° C., and 100˜160° C. is preferred for 10 minutes up to 2 hours. After the thermal treatment of (1) or (2), a finished product of crystalline ITO layer with a given conductivity is availed. As mentioned earlier, the two-stage crystalline film process yield a finished product with oxygen vacancy concentration lower than that from using the single stage film process. The finished product using the two-stage film process of the present invention has lower concentration of oxygen vacancy than that manufactured with single stage crystalline film process; therefore, the finished product using the manufacturing process of the present invention is less vulnerable to high heat and humidity while providing better environment durability property, thus the variation rate of sheet resistance is smaller resulting in good uniformity of the entire ITO layer. FIG. 3 shows variations of sheet resistance under different temperatures of ITO glass finished products respectively manufactured from using the single stage crystalline film process of the prior art and the two-stage crystalline film process of the present invention. As illustrated, the ITO glass finished product of the single stage film process is observe with wild variation of sheet resistance in the range of 25˜350° C. with a sheet resistance variation greater than 200% at 350° C. while stable variation of sheet resistance is observed with the ITO glass finished product using the two-stage crystalline film process and the sheet resistance variation at 350° C. is lower than 50%. Therefore, finished product from using the two-stage crystalline film process of the present invention has the advantage of small sheet resistance variation rate and being less vulnerable to impacts from high heat.

FIG. 4 shows variations of sheet resistance uniformity under different temperatures of ITO glass finished products respectively from using the single stage crystalline film process of prior art and the two-stage crystalline film process of the present invention. As illustrated, significant variation of uniformity of the ITO glass finished product from the single stage film process is observed within a range of 25˜350° C., more than 9% at 350° C.; while stable uniformity is observed with the ITO glass finished product from the two-stage crystalline film process with a variation in uniformity staying below 3% at 350° C. Therefore, the finished product availed from using the two-stage crystalline film process of the present invention demonstrates better uniformity and is less subject to humidity.

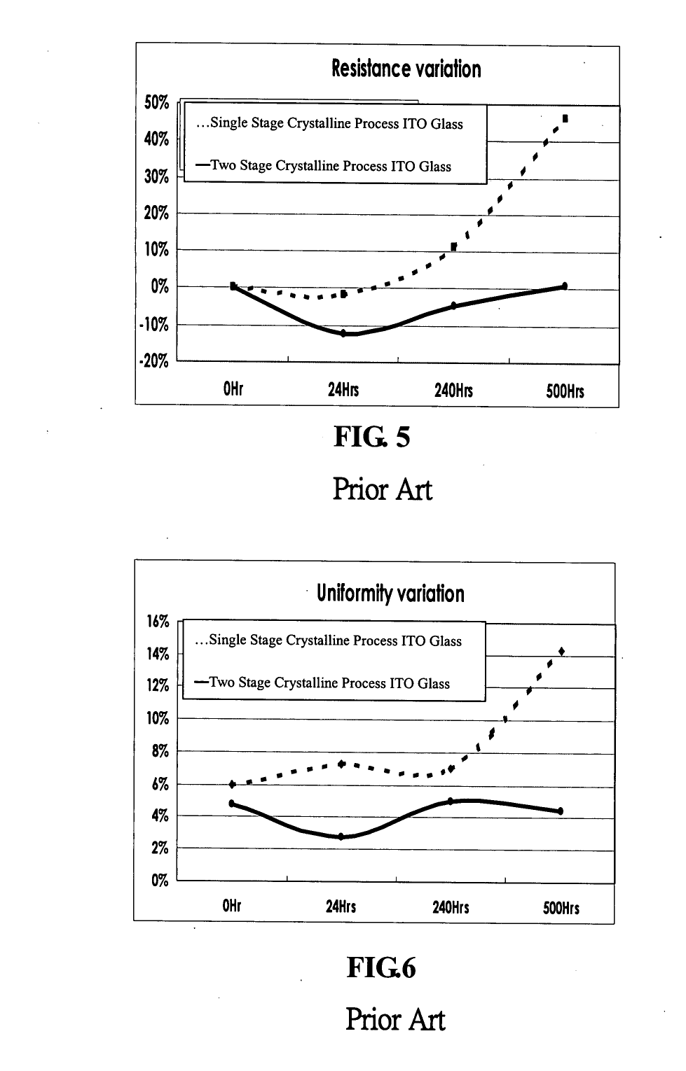

FIG. 5 shows variations of sheet resistance under 60° C., 90% RH, 500 hours of ITO glass finished products respectively from using the single stage crystalline film process of prior art and the two stage crystalline film process of the present invention. As illustrated, the ITO glass finished product from the single stage crystalline film process is observed with great variation of sheet resistance within 500 hours, and more than 40% at 500^{th} hour while the ITO glass finished product from the two-stage film process is observed with stable sheet resistance variation, approaching 0% even at the 500^{th} hour. Therefore, the sheet resistance variation of the finished product using the two-stage crystalline film process of the present invention is small and the ITO layer is less vulnerable to impacts from humidity.

FIG. 6 shows variations of sheet resistance uniformity under 60° C., 90% RH, and 500 hours of ITO glass finished products respectively from using the single stage crystalline film process of prior art and the two stage crystalline film process of the present invention. As illustrated, a significant variation of uniformity is observed within 500 hours of the ITO glass finished product from the single stage film process, and more than 14% at the 500^{th} hour while the finished product of ITO glass finished product is from the two-stage crystalline film process is observed with stable uniformity, and lower than 6% even at the 500^{th} hour. Therefore, the finished product form the two-stage crystalline film process of the present invention provides better uniformity and is less vulnerable to impacts from humidity. Furthermore, when compared to the single crystalline film process of the prior art given with the same specification of the finished product, the crystalline of the ITO layer produced using the two-stage crystalline film process is comparatively more refine, the grains are in greater size, and the surface is rougher at Ra reaching 0.4-1.2 nm for the ITO film to become more scratch resisting and provide longer service life.

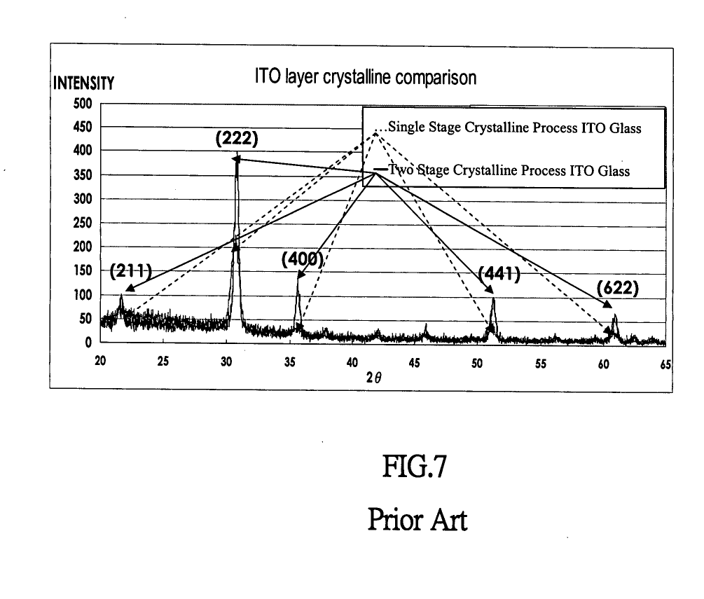

FIG. 7 is an X-ray diffraction pattern showing analysis of crystalline extents of ITO glass finished products respectively from using the single stage crystalline film process of prior art and the two-stage crystalline film process of the present invention. As illustrated, the crystalline extent (peaks of ITO crystal over 211, 222, 400, 441, and 622 faces) of the ITO glass from the two-stage crystalline film process is higher than that as observed from the ITO glass finished product from the single-stage crystalline film process (peaks of ITO crystal over 211, 222, 400, 441, and 622 faces). The higher the extent of crystalline is, ITO is more refine and better friction resisting, and better performance in pen test in terms of the touch panel.

Whereas in the single stage of crystalline film process of the prior art for preparation of the ITO layer, it takes to have the glass substrate heated up to a range of 200˜400° C. followed with sputtering at same high temperature before drastic cooling down to weaken the strength of the glass after the cycle of high temperature and drastic temperature drop. Furthermore, the single stage crystalline film process is not applicable to plastic substrate since the plastic substrate cannot take the high temperature process range process. In the present invention, a slow and stable thermal treatment is provided for ITO film process in the two-stage crystalline film process of the present invention, it is not necessary to heat up the substrate to a higher temperature range and drastic temperature drop after that; therefore, there is no problem of compromising the strength of the substrate.

Using of the two-stage crystalline film process for the preparation of the ITO layer, the sheet resistance range of the ITO layer may reach a range approximately of 200˜1500Ω/square, and 400˜600Ω/square inter alia. Furthermore, the film thickness of the ITO layer formed by using the manufacturing process of the present invention may reach a range approximately of 15˜50 nm, and 20˜35 nm inter alia.

A structure containing the ITO film produced to from the two-stage crystalline film process of the present invention involves having developed an ITO layer on a glass substrate; and the ITO layer is provided with an sheet resistance approximately of 200 up to 1500Ω/square and/or a film thickness of 15 up to 50 nm. The structure may be further applied in a structure of touch screen.

However, it is to be noted that the preferred embodiments disclosed in the specification and the accompanying drawings are not limiting the present invention; and that any construction, installation, or characteristics that is same or similar to that of the present invention should fall within the scope of the purposes and claims of the present invention.

I claim:

1. An ITO layer manufacturing process comprising in sequence:
a. Preparing a substrate;
b. Forming a semi-finished product by having developing an ITO layer on the surface of the substrate using a sputtering process in a sputtering to chamber at a temperature below 200° C.; and
c. Forming a finished product by having the semi-finished product placed in or passing through a heating device to go through a thermal treatment at a preset temperature.

2. The ITO layer manufacturing process as claimed in claim 1, wherein a crystalline state ITO layer is formed of the finished product after completing the thermal treatment in Step c.

3. The ITO layer manufacturing process as claimed in claim 1, wherein the substrate is related to a transparent substrate.

4. The ITO layer manufacturing process as claimed in claim 3, wherein the transparent substrate is related to a glass substrate.

5. The ITO layer manufacturing process as claimed in claim 4, wherein the glass substrate is related to a soda lime glass or quartz glass.

6. The ITO layer manufacturing process as claimed in claim 3, wherein, the transparent substrate relates to a plastic substrate.

7. The ITO layer manufacturing process as claimed in claim 6, wherein the plastic substrate is related to a Polycarbonate (PC), PMMA or PET substrate.

8. The ITO layer manufacturing process as claimed in claim 7, wherein the PC substrate is preferred for the plastic substrate.

9. The ITO layer manufacturing process as claimed in claim 1, wherein the substrate is not preheated before entering Step b.

10. The ITO layer manufacturing process as claimed in claim 1, wherein the preset temperature range falls between 150° C. and 400° C.

11. The ITO layer manufacturing process as claimed in claim 1, wherein the present temperature range falls between 150° C. and 400° C.; and a range of 300˜400° C. is preferred.

12. The ITO layer manufacturing process as claimed in claim 1, wherein the preset temperature is below 200° C.

13. The ITO layer manufacturing process as claimed in claim 1, wherein the preset temperature falls within a range of 100-160° C.

14. The ITO layer manufacturing process as claimed in claim 2, wherein a sheet resistance range of the ITO layer in crystalline state is approximately of 200 up to 1500Ω/square.

15. The ITO layer manufacturing process as claimed in claim 2, wherein a sheet resistance range of the ITO layer in crystalline state is approximately of 400 up to 600Ω/square.

16. The ITO layer manufacturing process as claimed in claim 2, wherein a range of film thickness of the ITO layer in crystalline state falls approximately between 15 and 50 nm.

17. The ITO layer manufacturing process as claimed in claim 2, wherein a range of film thickness of the ITO layer in crystalline state falls approximately between 25 and 35 nm.

18. The ITO layer manufacturing process as claimed in claim 1, wherein a thermal treatment lasting 30 minutes up to 3 hours is provided.

19. The ITO layer manufacturing process as claimed in claim 1, wherein a thermal treatment last ten minutes up to two hours is provided.

20. A structure provided with an ITO layer comprising:
a substrate; and
an ITO layer formed on the substrate; wherein the ITO layer is given a sheet resistance range approximately of 200 up to 1500Ω/square and a film thickness of 15 up to 50 nm.

21. The structure provided with the ITO layer as claimed in claim 20, wherein the substrate is related to a transparent substrate.

22. The structure provided with the ITO layer as claimed in claim 21, wherein the transparent substrate is related to a glass substrate.

23. The structure provided with the ITO layer as claimed in claim 22, wherein the glass substrate is related to a soda lime glass or a quartz glass.

24. The structure provided with the ITO layer as claimed in claim 21, wherein, the transparent substrate relates to a plastic substrate.

25. The structure provided with the ITO layer as claimed in claim 24, wherein the plastic substrate is related to a polycarbonate (PC), PMMA or PET substrate.

26. The structure provided with the ITO layer as claimed in claim 25, wherein the PC substrate is preferred.

27. A touch screen comprised of at least the structure provided with the ITO layer as claimed in claim 20.

28. The ITO layer manufacturing process as claimed in claim 1, wherein the temperature below 200° C. relates to that under manufacturing process conditions without heating up the sputtering chamber.
